(19) United States
(12) Patent Application Publication
(10) Pub. No.: US 2023/0239993 A1
(43) Pub. Date: Jul. 27, 2023

(54) COOLING SYSTEMS FOR A CIRCUIT BOARD

(71) Applicant: Microsoft Technology Licensing, LLC, Redmond, WA (US)

(72) Inventor: Wade J. DOLL, Enumclaw, WA (US)

(21) Appl. No.: 17/585,290

(22) Filed: Jan. 26, 2022

(51) Int. Cl. H05K 1/02

(52) U.S. Cl. CPC H05K 1/0203; H05K 7/20218

(57) ABSTRACT

A cooling system for a circuit board includes a conforming layer that conforms to the profile of the circuit board, including a base and at least one heat generating component. A cap is connected to the conforming layer and offset from the conforming layer with a gap. A working fluid is flowed through the gap and used to cool the heat generating component. This allows for a low-cost and flexible cooling system for a circuit board without a redesign of a cold plate with each change to the circuit board.

### CROSS-REFERENCE TO RELATED APPLICATIONS

N/A.

### BACKGROUND

Processors and other computing components generate heat during operation. If the heat is not dissipated, then a processor or other computing component may become overheated, which may lead to reduced performance and even damage of the component. Conventionally, a processor or other computing component is cooled using a cooling system.

One mechanism used to cool computing devices is to build a “cold plate” that connects to the circuit board. A cold plate may include a structure that directs a cold fluid, such as water or other working fluid, directly to a computing component to absorb the heat. Conventional cold plates are specifically designed to match the geometry of a specific circuit board, leading to customized cold plates for each build of a circuit board.

### BRIEF SUMMARY

In some embodiments, a circuit board includes a cooling system. The circuit board includes a base and a heat generating component extending from the base. A conforming layer is thermally connected to the heat generating component. The conforming layer is conformed to a profile of the heat generating component. A cap is offset from the conforming layer with a gap. The cap is connected to the conforming layer and configured to receive a working fluid in the gap between the cap and the conforming layer.

In other embodiments, a method for cooling a heat generating component on a circuit board includes fitting a conforming layer to a profile of the circuit board. A cap is connected to the conforming layer and offset from it with a gap. A working fluid is flowed through the gap between the cap and the conforming layer.

In yet other embodiments, a circuit board includes a base and a heat generating component connected to the base. A heat collection layer is located on top of the heat generating component and thermally connected to the heat generating component. The heat collection layer conforms to a shape of the base and the heat generating component. A working fluid is located on top of the heat collection layer and configured to collect heat from the heat generating component. A cap is located on top of the working fluid, a gap between the heat collection layer and the cap containing the working fluid.

This summary is provided to introduce a selection of concepts that are further described below in the detailed description. This summary is not intended to identify key or essential features of the claimed subject matter, nor is it intended to be used as an aid in limiting the scope of the claimed subject matter.

Additional features and advantages of embodiments of the disclosure will be set forth in the description which follows, and in part will be obvious from the description, or may be learned by the practice of such embodiments. The features and advantages of such embodiments may be realized and obtained by means of the instruments and combinations particularly pointed out in the appended claims. These and other features will become more fully apparent from the following description and appended claims, or may be learned by the practice of such embodiments as set forth hereinafter.

### BRIEF DESCRIPTION OF THE DRAWINGS

In order to describe the manner in which the above-recited and other features of the disclosure can be obtained, a more particular description will be rendered by reference to specific implementations thereof which are illustrated in the appended drawings. For better understanding, the like elements have been designated by like reference numbers throughout the various accompanying figures. While some of the drawings may be schematic or exaggerated representations of concepts, at least some of the drawings may be drawn to scale. Understanding that the drawings depict some example implementations, the implementations will be described and explained with additional specificity and detail through the use of the accompanying drawings in which:

FIG. 1-1 through FIG. 1-3 are representations of perspective view of a circuit board and a cooling system, according to at least one embodiment of the present disclosure;

FIG. 2-1 through FIG. 2-3 are representations of a cross-sectional view of a circuit board and a cooling system, according to at least one embodiment of the present disclosure;

FIG. 3 is a representation of a circuit board and cooling system having two heat generating components, according to at least one embodiment of the present disclosure;

FIG. 4 is a representation of a circuit board and a cooling system having two heat generating components, according to at least one embodiment of the present disclosure;

FIG. 5 is a representation of a circuit board and a cooling system having two differently sized heat generating components, according to at least one embodiment of the present disclosure;

FIG. 6 is a representation of a circuit board and a cooling system, according to at least one embodiment of the present disclosure; and

FIG. 7 is a flowchart of a method for cooling a circuit board, according to at least one embodiment of the present disclosure.

### DETAILED DESCRIPTION

This disclosure generally relates to devices, systems, and methods for building and cooling circuit boards. A circuit board includes a heat generating component. A thermoplastic sheet is conformed to the profile or approximate shape of the circuit board, including the shape of the heat generating component. The thermoplastic sheet is thermally connected to the heat generating component, such that the heat generating component transfers heat to the thermoplastic sheet. A cap is connected to the thermoplastic sheet, and the cap and the thermoplastic sheet form a gap between them. A working fluid is transmitted through the gap. The working fluid collects the heat from the thermoplastic and the fluid transfers it away from the circuit board as the fluid is flowed through the gap.

Conventionally, a cooling system for a circuit board includes a specialized cold plate that is specially designed and constructed for a particular circuit board design. Such specialized cold plates are expensive and time-consuming to design and build. In accordance with at least one embodiment of the present disclosure, the thermoplastic sheet may be conformed to the profile of the circuit board. For example, the thermoplastic sheet may be shrink-wrapped to the profile of the circuit board. A cap may be connected to the thermoplastic sheet, forming a gap between the thermoplastic sheet and the cap. A working fluid may be flowed through the gap, which may absorb the heat from any heat generating components, and the thermoplastic sheet may protect the components of the circuit board from the working fluid. In this manner, cooling systems of the present disclosure may have a reduced design time and overall cost.

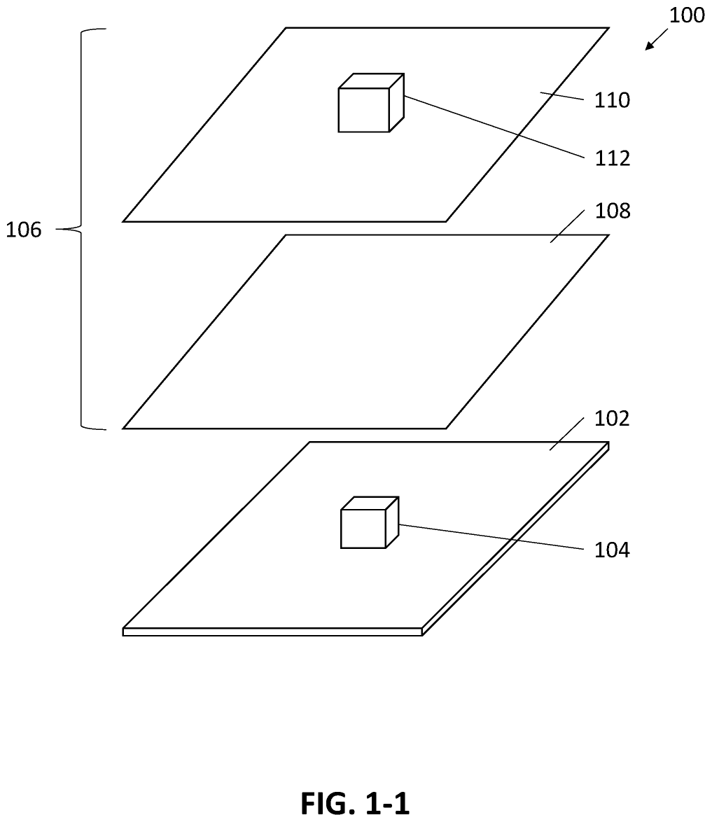

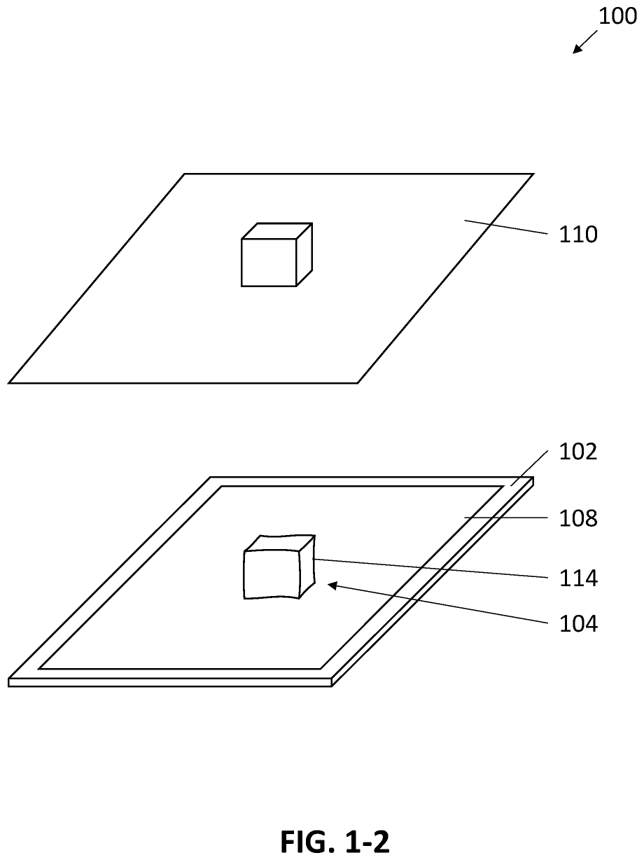

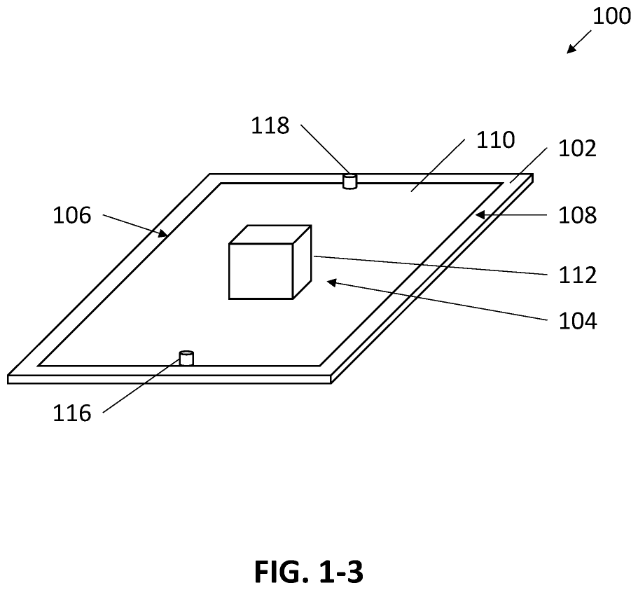

FIG. 1-1 is a representation of a schematic exploded view of a circuit board 100, according to at least one embodiment of the present disclosure. The circuit board 100 includes a base 102. The base 102 may have one or more components connected to it, such as a heat generating component 104. The heat generating component 104 may be any heat generating component 104, such as a processor, memory, a switch, a battery, a voltage regulator, a heat transfer device (e.g., a vapor chamber, heat pipe, and the like), any other heat generating component, and combinations thereof.

In some embodiments, the heat generating component 104 may be a low-power heat generating component. For example, the heat generating component 104 may have a heat generation. In some embodiments, the heat generation may be in a range having an upper value, a lower value, or upper and lower values including any of less than 1 W/cm², 1 W/cm², 2 W/cm², 3 W/cm², 4 W/cm², 5 W/cm², 6 W/cm², 7 W/cm², 8 W/cm², 9 W/cm², 10 W/cm², 11 W/cm², 12 W/cm², 13 W/cm², 14 W/cm², 15 W/cm², 16 W/cm², 17 W/cm², 18 W/cm², 19 W/cm², 20 W/cm², or any value therebetween. For example, the heat generation may be greater than 1 W/cm². In another example, the heat generation may be less than 20 W/cm². In yet other examples, the heat generation may be any value in a range between 1 W/cm² and 20 W/cm². In some embodiments, it may be critical that the heat generation is less than 20 W/cm² to allow the cooling system to transfer the heat away from the heat generating component 104.

In some embodiments, the circuit board 100 may include a cooling system 106. The cooling system 106 includes a conforming layer 108 and a cap 110. The conforming layer 108 may be formed from a thermoplastic sheet and may be configured to conform to a contour of the base 102 and any connected components, such as the heat generating component 104. For example, the conforming layer 108 may be shrink wrapped to the base 102 and the heat generating component 104. This may allow the conforming layer to become connected to the base 102 and the heat generating component 104.

When the cooling system 106 is assembled, the cap 110 may be placed over the conforming layer 108. The cap 110 may include one or more hollow extensions 112 that are shaped with the approximate profile of the base 102 and any connected components. Because the conforming layer 108 conforms to the profile of the base 102 and its connected components, when the cap 110 is placed over the conforming layer, any components extending from the base 102, and the overlaid conforming layer 108, may extend into the hollow extension 112.

In accordance with at least one embodiment of the present disclosure, a working fluid may be flowed through a gap between the conforming layer 108 and the cap 110. The conforming layer 108 may transfer heat to the working fluid. The working fluid may then flow out of the cooling system 106 and transfer the heat out of the cooling system 106.

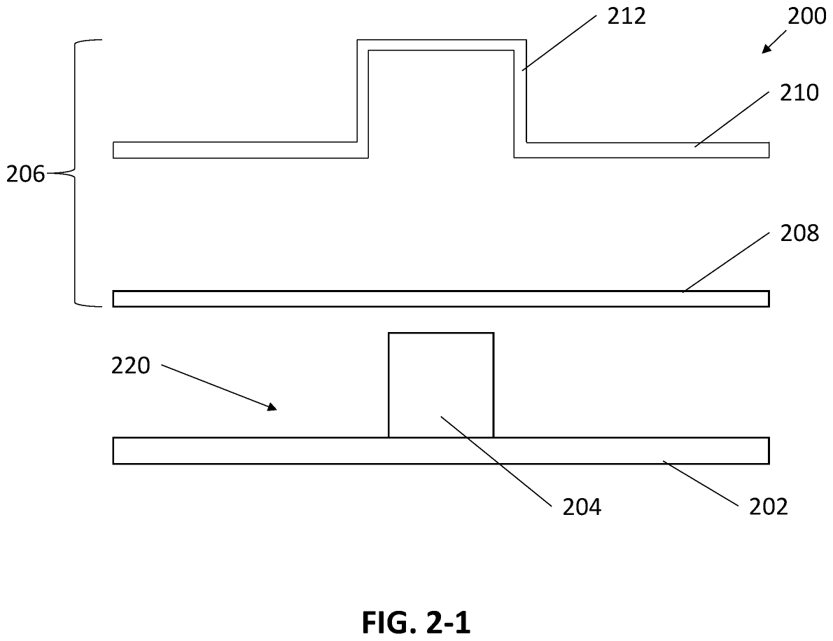

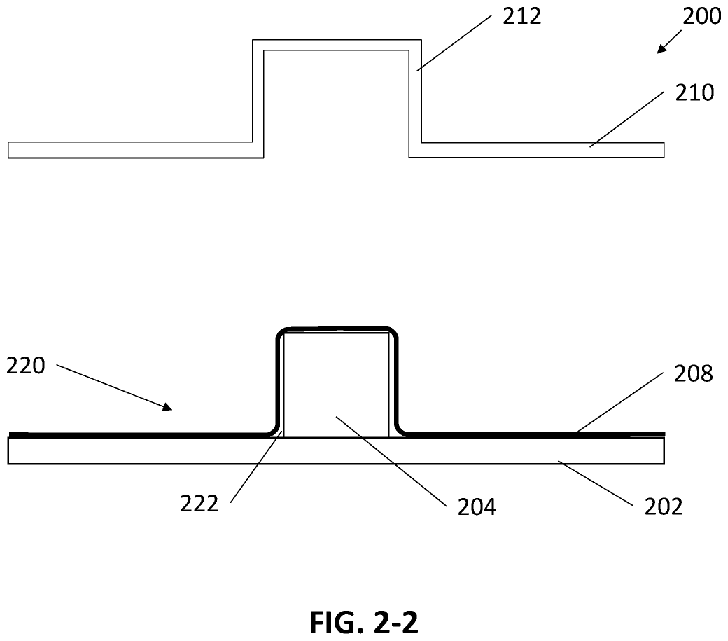

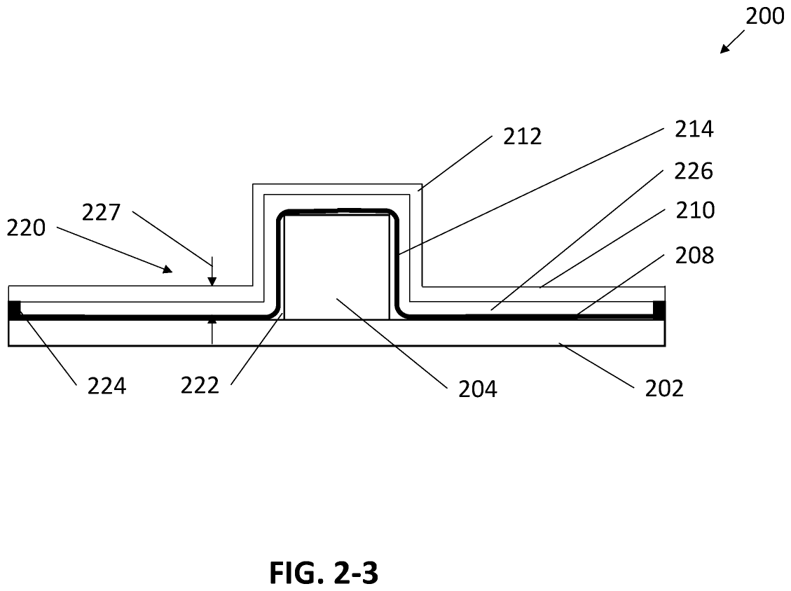

FIG. 1-2 is a representation of the circuit board 100 of FIG. 1-1 with the conforming layer 108 being conformed to the base 102. As may be seen, the conforming layer 108 has conformed to the profile of the base 102, including a profile of the heat generating component 104. When the conforming layer 108 is conformed to the base 102, the conforming layer 108 may result in a conforming protrusion 114. The heat generating component 104 may be inserted into the conforming protrusion 114. As discussed herein, the conforming layer 108 may be thermally connected to the heat generating component 104. The thermal connection to the heat generating component 104 may cause the conforming layer 108 to heat from the heat generating component.

In some embodiments, to conform the conforming layer to the base 102 and any extending components, the conforming layer 108 may be shrink wrapped to the base. The conforming layer 108 may be formed from a thermoplastic layer. The thermoplastic layer may become malleable at or above a glass transition temperature. As the thermoplastic layer is heated to the glass transition temperature, the thermoplastic layer may be molded to the base 102. In some embodiments, the thermoplastic layer may be vacuum sealed to the base 102. For example, the thermoplastic layer and the base 102 (and any extending components) may be placed in a vacuum bag or chamber and the air removed from the vacuum bag or chamber. This may cause the thermoplastic layer to conform to the shape of the base 102.

In some embodiments, the conforming layer 108 may be formed to the shape of the base 102 and any extending components prior to being connected to the base 102. For example, the conforming layer 108 may be formed to the shape of a dummy or other block having the same size and shape as the base 102. After being formed in the shape of the base 102, the conforming layer may be connected to the base 102. This may help to protect the base 102 and any connected components from being damaged during shrink wrapping or other conforming process.

After the conforming layer 108 has been shaped, the cap 110 may be connected to the conforming layer 108. For example, the cap 110 may be connected to the conforming layer 108 after the conforming layer 108 is connected or to the base 102. In some embodiments, the cap 110 may be connected to the conforming layer 108 before the conforming layer 108 before the conforming layer 108 is connected to the base 102.

As may be seen in FIG. 1-3, when the cap 110 is connected to the conforming layer 108 and placed on the base 102, the heat generating component 104 may be inserted into the hollow extension 112. As may be understood, because the conforming protrusion 114 may be inserted into the hollow extension 112. When the cap 110 is connected to the conforming layer 108, the cooling system 106 may be assembled.

As discussed further herein, the cooling system 106 includes a gap between the cap 110 and the conforming layer 108 Put another way, the cap 110 may be connected to the conforming layer 108 and offset with a gap. A working fluid may be flowed through the gap to collect and remove heat from the heat generating component 104. In some embodiments, the working fluid may flow into the cooling system 106 through an inlet 116 and out through an outlet 118. The inlet 116 may be hydraulically connected to the outlet 118. Put another way, the working fluid may flow freely between the inlet 116 and the outlet 118. For example, a pump may pump the working fluid into the gap through the inlet 116 and out of the gap through the outlet 118.

As may be seen, the hollow extension 112 may be located between the inlet 116 and the outlet 118. As the working fluid is pumped through the gap, then the working fluid may flow through the gap between the hollow extension 112 and the conforming protrusion 114. In this manner, heat transferred to the conforming layer 108 may be transferred to the fluid. As the fluid is transferred out of the gap, the heat generated by the heat generating component 104 may be transferred out of the cooling system 106. In some embodiments, the interior of the cooling system 106 may include one or more ridges, diversions, or posts that may direct the fluid through the interior of the cooling system 106 (e.g., through the gap) and across the heat generating component 104.

As may be understood, when the cap 110 is connected to the conforming layer 108, the connection between the cap 110 and the conforming layer 108 may be fluid-tight. Put another way, gap may be fluid tight such that the only way that fluid can get into and out of the gap is through the inlet 116 and the outlet 118. This may help to protect the electric components of the circuit board from leaks or other contact with the working fluid.

FIG. 2-1 is a representation of an exploded cross-sectional view of a circuit board 200, according to at least one embodiment of the present disclosure. The circuit board 200 includes a base 202 and a heat generating component 204 that extends up (e.g., in the “z-plane”) from the base 202. A cooling system 206 includes a conforming layer 208 and a cap 210. The cap 210 includes a hollow extension 212.

During assembly of the cooling system 206, the conforming layer 208 may be molded onto the base 202 and any protruding components, such as the heat generating component 204. As may be seen in FIG. 2-1, the conforming layer 208 has changed shape to conform to the profile 220 of the base 202 and the protruding heat generating element. As discussed herein, the conforming layer 208 may be molded to the profile 220 of the base 202 and the heat generating component 204. The conforming layer 208 may be molded to the profile 220 of the base 202 in any manner, such as through vacuum sealing, physical molding, or other mechanism. In some embodiments, the conforming layer 208 may be formed from a thermoplastic. When the thermoplastic is heated above a glass transition temperature, the conforming layer 208 may become moldable and molded to the shape of the profile 220. In some embodiments, the conforming layer may be formed from any material, such as a metal foil, a ceramic, any other material, and combinations thereof.

In some embodiments, when the conforming layer 208 has been molded to the profile 220 of the base and the heat generating component 204, the conforming layer 208 may contact at least one component of the circuit board 200. For example, the conforming layer 208 may contact the base 202 and/or the heat generating component 204. In some embodiments, the conforming layer 208 may directly contact the base 202 and/or the heat generating component 204. For example, the conforming layer 208 may contact the base 202 and/or the heat generating component 204 with no intervening materials.

In some embodiments, the conforming layer 208 may be at least partially offset from the base 202 and/or the heat generating component. For example, a conforming void 222 may be formed between the conforming layer 208 and the base 202 and/or the heat generating component 204. In some embodiments, the conforming void 222 may be filled with air. In some embodiments, the conforming void 222 may be filled with a thermally conductive material, such as a thermo gel or other thermally conductive gel that may conform to the shape of the base 202 and/or the heat generating component 204. In some embodiments, the conforming void 222 may be formed because the conforming layer 208 does not perfectly change shape to fit each corner, nook, and cranny in the profile 220. In some embodiments, the conforming void 222 may be formed because the conforming layer 208 is molded to the shape of the profile 220 prior to being connected to the base 202 and/or the heat generating component 204.

The conforming void 222 may have a void size, which may be how far offset from the components of the circuit board 200. In some embodiments, the void size may be in a range having an upper value, a lower value, or upper and lower values including any of 25 microns, 50 microns, 75 microns, 100 microns, 125 microns, 150 microns, or any value therebetween. For example, the void size may be greater than 25 microns. In another example, the void size may be less than 150 microns. In yet other examples, the void size may be any value in a range between 25 microns and 150 microns. In some embodiments, it may be critical that the void size is less than 150 microns to promote efficient heat transfer between the heat generating component 204 and the conforming layer 208, based on, for example, the manufacturability of conforming layer 208 and/or the maximum gap sizes for thermo gel.

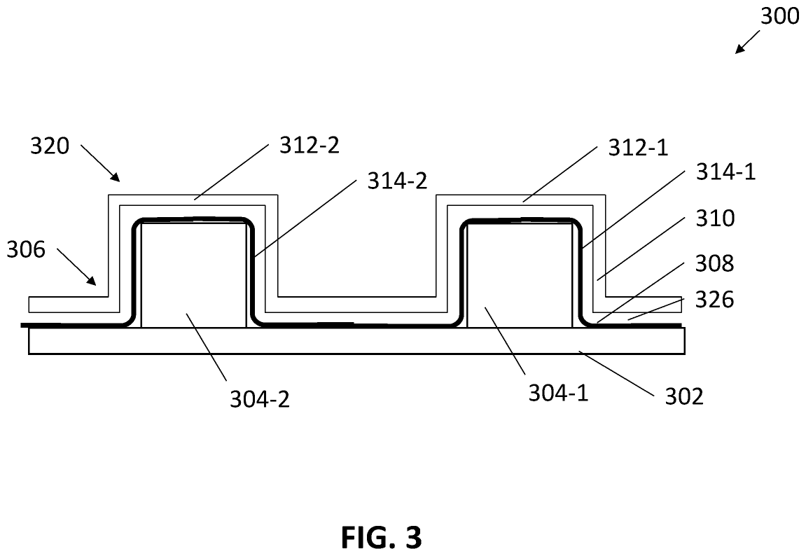

After the conforming layer 208 has been molded to the profile 220 and connected to the base 202 and the heat generating component 204, the cap 210 may be connected to the conforming layer 208. In some embodiments, the cap 210 may have a shape that approximately matches the profile 220 of the base 202 and the heat generating component 204. For example, as may be seen in FIG. 2-3, the hollow extension 212 of the cap 210 may be sized and positioned to allow the protruding heat generating component 204 to extend up into the hollow extension 212.

The cap 210 may be sealed to the conforming layer 208 with a seal 224. In some embodiments, the cap 210 may be welded to the conforming layer 208 to form the seal 224 with a plastic weld. In some embodiments, the seal 224 may be formed from an adhesive, such as a contact cement, a radio frequency activated adhesive, a pressure-sensitive adhesive, a thermal adhesive, any other adhesive, and combinations thereof. In some embodiments, the seal 224 may be formed with a mechanical connection.

In accordance with at least one embodiment of the present disclosure, the seal 224 may be formed to be liquid tight. Put another way, a liquid flowing through a gap 226 between the cap 210 and the conforming layer 208 may not exit the gap 226 at or through the seal 224. The liquid may only enter and exit the gap 226 through an inlet and an outlet.

In some embodiments, the conforming layer 208 may be formed from a thermally conductive material. For example, the conforming layer 208 may be formed from a thermally conductive thermoplastic. In some embodiments, the conforming layer 208 may be formed from a plastic that has thermally conductive particles embedded or entrained therein. For example, the plastic may have carbon, metal, ceramic, or other thermally conductive particles embedded therein. In some embodiments, the conforming layer 208 may be formed from any other material, such as a metal foil. In some embodiments, the conforming layer 208 may be an insulating material. An insulating conforming layer 208 may help to prevent shorts and other unintended or undesired electrical transmission across the conforming layer.

In some embodiments, the conforming layer 208 may be thermally connected to the heat generating component 204. For example, as discussed herein, the conforming layer 208 may be in direct contact with the heat generating component 204. Contact of the conforming layer 208 with the heat generating component 204 may transfer heat from the heat generating component to the conforming layer. In some embodiments, the conforming layer 208 may be thermally connected to the heat generating component 204 through an indirect contact. For example, as discussed herein, a conforming void 222 between the heat generating component 204 and the conforming layer 208 may be filled with a thermally conductive material. Heat generated by the heat generating component 204 may be transferred to the conforming layer 208 through the thermally conductive material.

As discussed herein, a working fluid may be flowed through the gap 226 between the cap 210 and the conforming layer 208. As may be seen, the gap 226 may extend between the conforming layer 208 and the cap 210 at the heat generating component 204. Put another way, the gap 226 may extend between the conforming protrusion 214 and the hollow extension 212. In this manner, as heat from the heat generating component 204 is absorbed by the conforming layer 208, the heat may be transferred to the working fluid in the gap 226. The heat may then be removed from the circuit board 200 when the working fluid is flowed out of the gap 226.

The gap 226 has a gap width 227, which may be the distance between an inner surface of the cap 210 and the conforming layer 208. In some embodiments, the gap width 227 may be in a range having an upper value, a lower value, or upper and lower values including any of 1 mm, 2 mm, 3 mm, 4 mm, 5 mm, 10 mm, 15 mm, 20 mm, or any value therebetween. For example, the gap width 227 may be greater than 1 mm. In another example, the gap width 227 may be less than 20 mm. In yet other examples, the gap width 227 may be any value in a range between 1 mm and 20 mm. In some embodiments, it may be critical that the gap width 227 is between 1 mm and 20 mm to provide sufficient room for a working fluid to flow through the gap 226, while, for example, providing sufficient heat transfer. In situations where the gap width 227 is greater than 20 mm, the fluid velocity may be too low and not enough fluid may pass through to facilitate sufficient thermal transfer.

In some embodiments, the working fluid may be a single-phase working fluid. For example, the heat generated by the heat generating component 204 (and transferred to the working fluid through the conforming layer 208) may heat, but not heat to the boiling point, the working fluid. This may help to keep the gap 226 clean and avoid pockets of gas or bubbles that may reduce the effectiveness of the cooling system 206. In some embodiments, the working fluid may be a two-phase working fluid. For example, the heat generated by the heat generating component 204 (and transferred to the working fluid through the conforming layer 208) may raise the temperature of the working fluid to the boiling point. As will be understood, boiling the working fluid may absorb additional heat due to the heat of vaporization of the working fluid.

In accordance with at least one embodiment of the present disclosure, the cooling systems 206 discussed herein may be cheaply and easily modifiable to various designs and builds of circuit boards 200. Indeed, the cooling systems may be cheaply and easily modifiable to last-minute changes in the design and structure of a circuit board 200. As discussed herein, conventionally, a cold plate may be specifically designed for a particular circuit board geometry, and small changes may change the design of the cold plate, thereby incurring additional engineering and manufacturing expenses. By molding a conforming layer 208 to the base 202 and the heat generating component 204, the specific geometry of a particular circuit board 200 may be unknown prior to assembling the cooling system 206. Assembling the cooling system 206 may occur without prior knowledge of the shape, contours, or components of a particular circuit board 200. This may help to reduce engineering and manufacturing costs, especially in light of last-minute changes to the design or structure of the circuit board 200.

In some embodiments, the cap 210 may be formed from a rigid material. For example, the cap 210 may be formed from a rigid plastic. This may help to increase the protection of components of the circuit board. In some embodiments, the cap 210 may be formed from the same material as the conforming layer 208. In some embodiments, the cap 210 may be formed from a different material than the conforming layer 208.

In some embodiments, the cooling system 206 of the present disclosure may be used independently. Put another way, the cooling system 206 may be the only cooling system 206 connected to the circuit board 200. In some embodiments, the cooling system 206 may be used in conjunction with a conventional cold plate. For example, the cooling system 206 may be connected to the low-power or low-heat portions of the circuit board, and a conventional cold plate may be connected to a higher power or higher heat portion of a circuit board. In this manner, the risk of a redesign may be reduced by only using the conventional cold plate on the high-heat portions.

As may be seen, the circuit board 200 may be comprised of a plurality of layers. A first layer, or a bottom layer, may be the base 202. The heat generating component 204 may be connected to the base 202 on top of the base 202. A conforming layer 208 or a heat collection layer may be located on top of the heat generating component 204. The conforming layer 208 or the heat collection layer may be thermally connected to the heat generating component 204. The conforming layer 208 or the heat collection layer may conform to a shape of the base 202 and the heat generating component 204. A working fluid is located on tope of the heat collection layer and is configured to collect heat from the heat generating component 204. A cap 210 may be located on top of the working fluid, a gap between the cap 210 and the heat collection layer containing the working fluid. In some embodiments, the cap 210 forms a seal with the heat collection layer, and the working fluid flows into the gap through an inlet and out through an outlet. In some embodiments, the heat generating component 204 is located between the inlet and the outlet.

FIG. 3 is a representation of a circuit board 300 having multiple heat generating components (collectively 304), according to at least one embodiment of the present disclosure. The circuit board 300 may include a base 302 having multiple components extending up from the base. For example, in the embodiment shown, a first heat generating component 304-1 and a second heat generating component 304-2 may be connected to and extend up from (e.g., in the z-plane) the base 302. In some embodiments, a cooling system 306 may be connected to the circuit board 300. The cooling system 306 may help to shed or remove the heat generated by the heat generating components 304.

As discussed herein, the cooling system 306 may be formed without prior knowledge of the shape of a profile of the circuit board 300. During assembly of the cooling system 306, a conforming layer 308 may be molded to the profile 320 of the circuit board 300, which may include the base 302, the first heat generating component 304-1 and the second heat generating component 304-2. The conforming layer 308 may initially be a flat sheet (as seen in FIG. 2-2). During molding, the conforming layer 308 may change shape to conform to the profile 320. This may cause the conforming layer 308 to form a first conforming protrusion 314-1 over the first heat generating component 304-1 and a second conforming protrusion 314-2 over the second heat generating component 304-2. In this manner, the particular shape and profile 320 of the circuit board 300 may be unknown prior to fitting the conforming layer 308 to the circuit board.

The cooling system 306 includes a cap 310 that is connected to the conforming layer 308. The cap 310 may be formed to approximate the profile 320 of the circuit board 300. For example, the 310 may include a first hollow extension 312-1 and a second hollow extension 312-2. The first heat generating component 304-1 and the first conforming protrusion 314-1 may extend into the first hollow extension 312-1, and the second heat generating component 304-2 and the second conforming protrusion 314-2 may extend into the second hollow extension 312-2.

In some embodiments, the cap 310 may be shaped to approximate the profile 320 of the circuit board 300. In some embodiments, the cap 310 may be shaped to within 1%, 2%, 3%, 4%, 5%, 6%, 7%, 8%, 9%, 10%, or more of the profile 320 of the circuit board. In some embodiments, the shape of the cap 310 may allow for a gap 326 to be formed between the conforming layer 308 and the cap 310. As discussed herein, the gap 326 may allow for a working fluid to pass between the conforming layer 308 and the cap 310 to cool the heat generating components 304. In some embodiments, the shape of the cap 310 may allow for changes in the design of the circuit board 300 without changing the shape or design of the cap 310.

As may be seen, the cap 310 may have a separate hollow extension 312 for each of the first heat generating component 304-1 and the second heat generating component 304-2. This may be based on the location of the heat generating components 304. The heat generating components 304 may be separated with a distance such that, if the gap 326 were to extend between the two heat generating components, then an excess amount of working fluid may be used to fill the gap 326, thereby increasing material costs. However, it should be understood that the cap 310 may extend between the first heat generating component 304-1 and the second heat generating component 304-2.

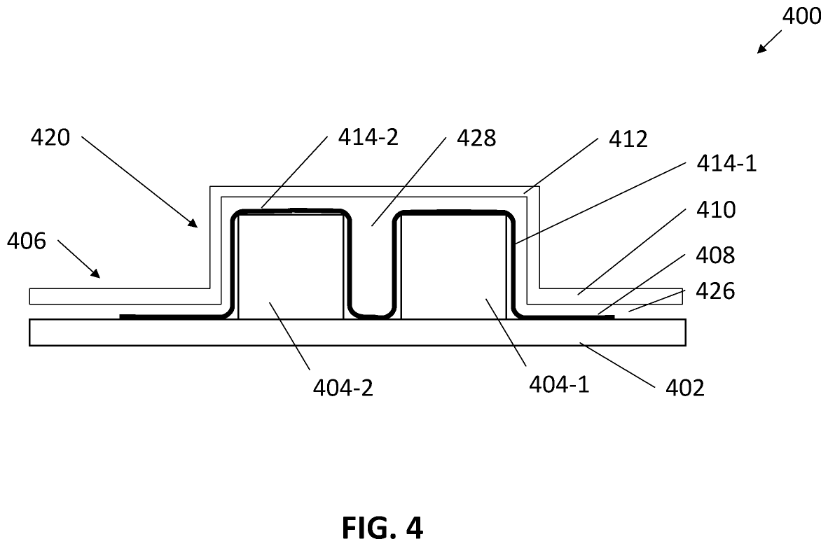

For example, FIG. 4 is a representation of a circuit board 400 with a cooling system 406 having a single hollow extension 412 that extends over two heat generating components (collectively 404), according to at least one embodiment of the present disclosure. In the embodiment shown, a first heat generating component 404-1 and a second heat generating component 404-2 extend upward from a base 402. The cooling system 406 includes a conforming layer 408 that is molded to a profile 420 of the circuit board 400, including the base 402, the first heat generating component 404-1 (forming a first conforming protrusion 414-1), and the second heat generating component 404-2 (forming a second conforming protrusion 414-2). The cooling system may include a cap 410 connected to the conforming layer 408, forming a gap 426 between the cap 410 and the conforming layer 408.

The cap 410 may include the single hollow extension 412 that extends over the first heat generating component 404-1 and the second heat generating component 404-2. Put another way, the first heat generating component 404-1 and the first conforming protrusion 414-1, as well as the second heat generating component 404-2 and the second conforming protrusion 414-2 may extend up into the hollow extension 412. A working fluid may pass through the gap 426 and a valley 428 between the first heat generating component 404-1 and the second heat generating component 404-2.

In some embodiments, the cap 410 may include a single hollow extension 412 because the first heat generating component 404-1 is separated from the second heat generating component 404-2 with a separation distance that is too narrow to include the material of the cap 410 and maintain a gap 426 of sufficient width to flow the working fluid through. In some embodiments, the cap 410 may include a single hollow extension 412 to increase a volume of working fluid that flows through the valley 428. An increased amount of working fluid in the valley may increase the mount of heat the working fluid may absorb. In some embodiments, the cap 410 may include a single hollow extension 412 to provide space for changes in the design of the circuit board 400, including design changes of the heat generating components, such as size, shape, location, number, any other design change, and combinations thereof.

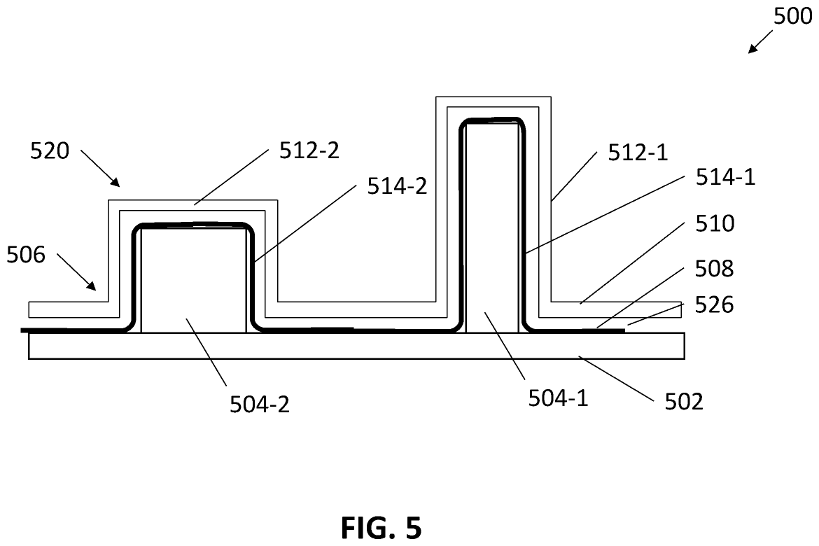

FIG. 5 is a representation of a circuit board 500 having a plurality of heat generating components (collectively 504) having different sizes, according to at least one embodiment of the present disclosure. The circuit board 500 has a cooling system 506 that may accommodate differently sized heat generating components 504. For example, as may be seen, a first heat generating component 504-1 has a width that is less than a height, while a second heat generating component 504-2 has a width that is approximately equal to the height. While two particular shapes and ratios are shown in FIG. 5, it should be understood that any number of heat generating components 504 and other components may be connected to the base 502.

The cooling system 506 may include a conforming layer 508 that is molded to or shaped to conform to the shape of a profile 520 of the circuit board. The profile 520 may include the shape of the base 502, the shape of the first heat generating component 504-1, and the shape of the second heat generating component 504-2. As may be seen, the conforming layer 508 conforms to the shape of the profile 520, including a first conforming protrusion 514-1 that conforms to the shape of the first heat generating component 504-1 and a second conforming protrusion 514-2 that conforms to the shape of the second heat generating component 504-2. The conforming layer 508 may conform to the profile 520 of the circuit board 500 during the molding process, such as during heat shrinking or other molding process.

The cooling system 506 further includes a cap 510 that is connected to the conforming layer 508. The cap 510 may include a first hollow extension 512-2 and a second hollow extension 512-2. The first heat generating component 504-1 (and the first conforming protrusion 514-1) may extend into the first hollow extension 512-1 and the second heat generating component 504-2 (and the second conforming protrusion 514-2) may extend into the second hollow extension 512-2. As may be seen, the cap 510 may be formed with a shape that approximates or approximately matches the profile 520 of the circuit board 500. This may allow for a gap 526 to be formed between the conforming layer 508 and the cap 510 and for fluid to flow therethrough.

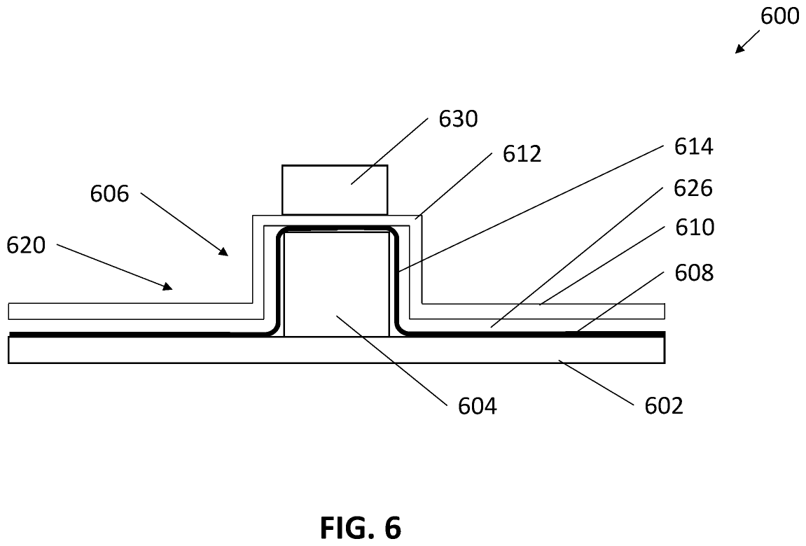

FIG. 6 is a representation of a circuit board 600 having a cap 610 that contacts a conforming layer 608, according to at least one embodiment of the present disclosure. The circuit board includes a base 602 that has one or more heat generating elements 604 extending therefrom. A cooling system 606 is connected to the circuit board. The cooling system 606 includes a conforming layer 608 that is molded to a profile 620 of the circuit board, including a shape of the base 602 and the heat generating component 604. A conforming protrusion 614 is molded to the heat generating component 604 and extends up from the base 602.

The cooling system 606 includes a cap 610 that is connected to the conforming layer 608. The cap 610 includes a hollow extension 612 that is located and shaped to receive the heat generating component 604 and the conforming protrusion 614. The cap 610 is offset from the conforming layer 608 to form a gap 626 between them. In some embodiments, at least a portion of the cap 610 may be in contact with the conforming layer 608. In the embodiment shown, the hollow extension 612 is in contact with the conforming layer 608 at the heat generating component 604.

In the embodiment shown, a cold plate 630 is connected to the cap 610 at the hollow extension 612 (e.g., opposite the conforming protrusion 614 across the cap 610). The heat generating component 604 may generate more heat than the fluid flowing through the gap 626 can remove by itself. Connecting a cold plate 630 to the cap at the hollow extension 612 may allow for a greater degree of cooling of the heat generating component.

In some embodiments, the cap 610 may be in contact with the conforming layer 608 at any location. This may help to provide structural support for the cap 610. For example, contact of the cap 610 with the conforming layer 608 may help to maintain the position of the cap 610 and may help to keep the gap 626 open.

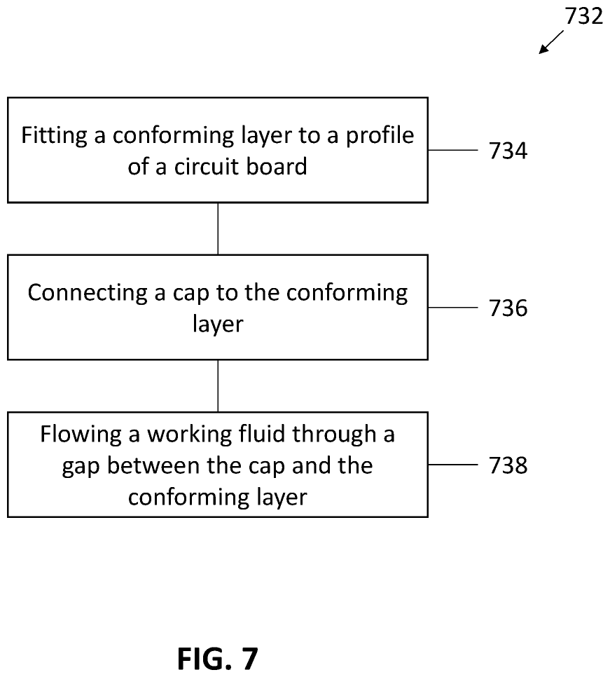

FIG. 7 is a flowchart of a method 732 for cooling a circuit board, according to at least one embodiment of the present disclosure. The method 732 includes fitting or molding a conforming layer to a profile of a circuit board at 734. As discussed herein, fitting the conforming layer to the profile of the circuit board may include shrink-wrapping the conforming layer to the circuit board. In some embodiments, shrink-wrapping the conforming layer may include heating the conforming layer to above a glass transition temperature. In some embodiments, after the conforming layer has been heated above the glass transition temperature, the conforming layer may be shrink-wrapped to the circuit board.

The method 732 may further include connecting a cap to the conforming layer at 736. The cap may be offset from the conforming layer with a gap. In some embodiments, the cap may be thermally welded to the conforming layer. The method 732 may further include flowing a working fluid through the gap between the cap and the conforming layer at 738. As discussed herein, the working fluid may collect heat from the heat generating component of the circuit board and remove the heat from the circuit board.

One or more specific embodiments of the present disclosure are described herein. These described embodiments are examples of the presently disclosed techniques. Additionally, in an effort to provide a concise description of these embodiments, not all features of an actual embodiment may be described in the specification. It should be appreciated that in the development of any such actual implementation, as in any engineering or design project, numerous embodiment-specific decisions will be made to achieve the developers' specific goals, such as compliance with system-related and business-related constraints, which may vary from one embodiment to another. Moreover, it should be appreciated that such a development effort might be complex and time consuming, but would nevertheless be a routine undertaking of design, fabrication, and manufacture for those of ordinary skill having the benefit of this disclosure.

The articles “a,” “an,” and “the” are intended to mean that there are one or more of the elements in the preceding descriptions. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features. For example, any element described in relation to an embodiment herein may be combinable with any element of any other embodiment described herein. Numbers, percentages, ratios, or other values stated herein are intended to include that value, and also other values that are “about” or “approximately” the stated value, as would be appreciated by one of ordinary skill in the art encompassed by embodiments of the present disclosure. A stated value should therefore be interpreted broadly enough to encompass values that are at least close enough to the stated value to perform a desired function or achieve a desired result. The stated values include at least the variation to be expected in a suitable manufacturing or production process, and may include values that are within 5%, within 1%, within 0.1%, or within 0.01% of a stated value.

A person having ordinary skill in the art should realize in view of the present disclosure that equivalent constructions do not depart from the spirit and scope of the present disclosure, and that various changes, substitutions, and alterations may be made to embodiments disclosed herein without departing from the spirit and scope of the present disclosure. Equivalent constructions, including functional “means-plus-function” clauses are intended to cover the structures described herein as performing the recited function, including both structural equivalents that operate in the same manner, and equivalent structures that provide the same function. It is the express intention of the applicant not to invoke means-plus-function or other functional claiming for any claim except for those in which the words ‘means for’ appear together with an associated function. Each addition, deletion, and modification to the embodiments that falls within the meaning and scope of the claims is to be embraced by the claims.

The terms “approximately,” “about,” and “substantially” as used herein represent an amount close to the stated amount that still performs a desired function or achieves a desired result. For example, the terms “approximately,” “about,” and “substantially” may refer to an amount that is within less than 5% of, within less than 1% of, within less than 0.1% of, and within less than 0.01% of a stated amount. Further, it should be understood that any directions or reference frames in the preceding description are merely relative directions or movements. For example, any references to “up” and “down” or “above” or “below” are merely descriptive of the relative position or movement of the related elements.

The present disclosure may be embodied in other specific forms without departing from its spirit or characteristics. The described embodiments are to be considered as illustrative and not restrictive. The scope of the disclosure is, therefore, indicated by the appended claims rather than by the foregoing description. Changes that come within the meaning and range of equivalency of the claims are to be embraced within their scope.

What is claimed is:

1. A circuit board including a cooling system, comprising:
a base;
a heat generating component extending from the base;
a conforming layer thermally connected to the heat generating component, the conforming layer conforming to a profile of the heat generating component; and
a cap offset from the conforming layer with a gap, the cap being connected to the conforming layer and configured to receive a working fluid in the gap between the cap and the conforming layer.

2. The circuit board of claim 1, wherein the cap is thermally welded to the conforming layer.

3. The circuit board of claim 1, wherein the cap is offset from the conforming layer by between 1 mm and 20 mm.

4. The circuit board of claim 1, wherein the conforming layer is thermally conductive.

5. The circuit board of claim 1, wherein the heat generating component has a heat generation of less than 20 W/cm².

6. The circuit board of claim 1, wherein the conforming layer is in direct contact with the heat generating component.

7. The circuit board of claim 1, wherein the conforming layer is separated from the heat generating component with a thermally conductive material.

8. The circuit board of claim 1, wherein the cap includes an inlet and an outlet, the inlet being hydraulically connected to the outlet through the gap.

9. The circuit board of claim 8, wherein the heat generating component is located between the inlet and the outlet.

10. The circuit board of claim 1, wherein the heat generating component includes a plurality of heat generating components, at least two of the plurality of heat generating components having a different size, and wherein the conforming layer conforms to the profile of each of the plurality of heat generating components.

11. A method for cooling a heat generating component on a circuit board, comprising:
fitting a conforming layer to a profile of the circuit board;
connecting a cap to the conforming layer, the cap being offset from the conforming layer with a gap; and
flowing a working fluid through the gap between the cap and the conforming layer.

12. The method of claim 11, wherein fitting the conforming layer includes shrink-wrapping the conforming layer to the circuit board and a profile of the heat generating component.

13. The method of claim 12, wherein shrink-wrapping the conforming layer includes heating the conforming layer to above a glass transition temperature.

14. The method of claim 12, wherein shrink-wrapping the conforming layer includes vacuum sealing the conforming layer.

15. The method of claim 11, wherein fitting the conforming layer includes fitting the conforming layer prior to connecting the conforming layer to the circuit board.

16. The method of claim 11, wherein flowing the working fluid through the gap includes flowing the working fluid across a portion of the conforming layer opposite the heat generating component.

17. The method of claim 11, wherein flowing the working fluid through the gap includes flowing a two-phase working fluid through the gap.

18. A circuit board, comprising:
a base;
a heat generating component connected to the base;
a heat collection layer located on top of the heat generating component and thermally connected to the heat generating component, the heat collection layer conforming to a shape of the base and the heat generating component;
a working fluid located on top of the heat collection layer and configured to collect heat from the heat generating component; and
a cap located on top of the working fluid, a gap between the heat collection layer and the cap containing the working fluid.

19. The circuit board of claim 18, wherein the cap forms a seal with the heat collection layer, the working fluid flowing into the gap through an inlet and out of the gap through an outlet.

20. The circuit board of claim 19, wherein the heat generating component is located between the inlet and the outlet.
